(19) United States
(12) Patent Application Publication
(10) Pub. No.: US 2025/0309609 A1
(43) Pub. Date: Oct. 2, 2025

(54) SEMICONDUCTOR OPTICAL DEVICE AND METHOD OF MANUFACTURING SEMICONDUCTOR OPTICAL DEVICE

(71) Applicant: SUMITOMO ELECTRIC INDUSTRIES, LTD., Osaka (JP)

(72) Inventor: Naoki FUJIWARA, Osaka-shi (JP)

(73) Assignee: SUMITOMO ELECTRIC INDUSTRIES, LTD., Osaka (JP)

(21) Appl. No.: 19/049,049

(22) Filed: Feb. 10, 2025

(30) Foreign Application Priority Data
Mar. 27, 2024 (JP) 2024-051046

(51) Int. Cl. H01S 5/02

(52) U.S. Cl. CPC H01S 5/0207; H01S 5/021

(57) ABSTRACT

A semiconductor optical device includes a substrate including a silicon layer, and a semiconductor device formed of a III-V group compound semiconductor and bonded to the silicon layer of the substrate. The silicon layer is provided with at least one trench, the at least one trench extends from a region overlapping the semiconductor device to a region outside the semiconductor device and is provided with a communicating port that communicates between a portion of the at least one trench in the region overlapping the semiconductor device and a portion of the at least one trench in the region outside the semiconductor device, and the communicating port in the at least one trench is a single communicating port.

### CROSS REFERENCE TO RELATED APPLICATIONS

This application claims priority based on Japanese Patent Application No. 2024-051046 filed on Mar. 27, 2024, and the entire contents of the Japanese patent application are incorporated herein by reference.

### TECHNICAL FIELD

The present disclosure relates to a semiconductor optical device and a method of manufacturing a semiconductor optical device.

### BACKGROUND

A hybrid semiconductor optical device can be formed by bonding a semiconductor device formed of a compound semiconductor and having an optical gain to a substrate such as a silicon on insulator (SOI) substrate (silicon photonics) on which a waveguide is formed. When hydrophilic bonding is performed in bonding step, water is generated. When the water is vaporized at the bonding interface, bubbles are generated, and the bonding becomes defective. A technique of providing trenches in the substrate for water drainage has been developed (for example, non-patent literature 1: Yiding Lin et al. “Geometry and Thermal Stress Analysis of In-plane Outgassing Channels in Al₂O₃-Intermediated InP (Die)-to-Si (Wafer) Bonding” ECS Journal of Solid State Science and Technology, 5 (2) P117-P123 (2016) and non-patent literature 2: Jiajie Lin et al. “Wafer-scale heterogeneous integration InP on trenched Si with a bubble-free interface” APL Materials 8, 051110 (2020)).

### SUMMARY

A semiconductor optical device according to the present disclosure includes a substrate including a silicon layer, and a semiconductor device formed of a III-V group compound semiconductor and bonded to the silicon layer of the substrate. The silicon layer is provided with at least one trench, the at least one trench extends from a region overlapping the semiconductor device to a region outside the semiconductor device and is provided with a communicating port that communicates between a portion of the at least one trench in the region overlapping the semiconductor device and a portion of the at least one trench in the region outside the semiconductor device, and the communicating port in the at least one trench is a single communicating port.

### BRIEF DESCRIPTION OF THE DRAWINGS

FIG. 1A is a plan view illustrating a semiconductor optical device according to a first embodiment.

FIG. 1B is a plan view illustrating a substrate.

FIG. 2A is a cross-sectional view illustrating a semiconductor optical device.

FIG. 2B is a cross-sectional view illustrating a substrate.

FIG. 2C is a cross-sectional view illustrating a substrate.

FIG. 2D is a cross-sectional view illustrating a substrate.

FIG. 3A is a schematic view illustrating a method of manufacturing a semiconductor optical device.

FIG. 3B is a schematic view illustrating a method of manufacturing a semiconductor optical device.

FIG. 4A is a plan view illustrating a method of manufacturing a semiconductor optical device.

FIG. 4B is a cross-sectional view illustrating a method of manufacturing a semiconductor optical device.

FIG. 4C is a cross-sectional view illustrating a method of manufacturing a semiconductor optical device.

FIG. 4D is a cross-sectional view illustrating a method of manufacturing a semiconductor optical device.

FIG. 5A is a plan view illustrating a method of manufacturing a semiconductor optical device.

FIG. 5B is a cross-sectional view illustrating a method of manufacturing a semiconductor optical device.

FIG. 5C is a cross-sectional view illustrating a method of manufacturing a semiconductor optical device.

FIG. 5D is a cross-sectional view illustrating a method of manufacturing a semiconductor optical device.

FIG. 6A is a plan view illustrating a method of manufacturing a semiconductor optical device.

FIG. 6B is a cross-sectional view illustrating a method of manufacturing a semiconductor optical device.

FIG. 6C is a cross-sectional view illustrating a method of manufacturing a semiconductor optical device.

FIG. 6D is a cross-sectional view illustrating a method of manufacturing a semiconductor optical device.

FIG. 7A is a plan view illustrating a method of manufacturing a semiconductor optical device.

FIG. 7B is a cross-sectional view illustrating a method of manufacturing a semiconductor optical device.

FIG. 7C is a cross-sectional view illustrating a method of manufacturing a semiconductor optical device.

FIG. 7D is a cross-sectional view illustrating a method of manufacturing a semiconductor optical device.

FIG. 8A is a plan view illustrating a method of manufacturing a semiconductor optical device according to a first comparative example.

FIG. 8B is a cross-sectional view illustrating a cross-section taken along line D-D of FIG. 8A.

FIG. 9A is a plan view illustrating a method of manufacturing a semiconductor optical device according to a second embodiment.

FIG. 9B is a plan view illustrating a substrate.

FIG. 10A is a plan view illustrating a method of manufacturing a semiconductor optical device according to a third embodiment.

FIG. 10B is a plan view illustrating a substrate.

FIG. 11 is a plan view illustrating a method of manufacturing a semiconductor optical device according to a second comparative example.

FIG. 12A is a plan view illustrating a method of manufacturing a semiconductor optical device according to a fourth embodiment.

FIG. 12B is a plan view illustrating a substrate.

FIG. 13 is a plan view illustrating a method of manufacturing a semiconductor optical device according to a fifth embodiment.

### DETAILED DESCRIPTION

The bonded semiconductor device is processed using wet-etching or the like. Etchants may enter through the trenches for water drainage, and the semiconductor device may be etched from the bonding interface. Peeling, performance degradation, or the like of the semiconductor device may occur. Thus, an object is to provide a semiconductor optical device and a method of manufacturing a semiconductor optical device that can prevent etching of the semiconductor device from a bonding interface.

### Description of Embodiments of Present Disclosure

First, the contents of embodiments of the present disclosure will be listed and explained.

(1) A semiconductor optical device according to an aspect of the present disclosure includes a substrate including a silicon layer, and a semiconductor device formed of a III-V group compound semiconductor and bonded to the silicon layer of the substrate. The silicon layer is provided with at least one trench, the at least one trench extends from a region overlapping the semiconductor device to a region outside the semiconductor device and is provided with a communicating port that communicates between a portion of the at least one trench in the region overlapping the semiconductor device and a portion of the at least one trench in the region outside the semiconductor device, and the communicating port in the at least one trench is a single communicating port. Since the number of the communicating ports is one, the etchant is less likely to enter into the trench. It is possible to prevent etching of the semiconductor device from the bonding interface.

(2) In the above (1), the at least one trench may include a plurality of trenches, and the communicating port in each of the plurality of trenches may be a single communicating port. Moisture can be discharged from the bonding interface through the plurality of trenches. Since the number of communicating ports included in the plurality of trenches is one, etchant is less likely to enter into. Etching of the semiconductor device from the bonding interface can be prevented.

(3) In the above (1) or (2), the silicon layer may include a waveguide, the silicon layer may have a first portion located on a side and a second portion located on an opposite side with reference to the waveguide, and the at least one trench may be provided in each of the first portion and the second portion. In both the first portion and the second portion, moisture can be discharged and etchant can be prevented from entering into.

(4) In any one of the above (1) to (3), the at least one trench may be present within a distance of 50 μm from any position at a bonding interface between the substrate and the semiconductor device. Since the distance to the trench is short, moisture reaches the trench and is easily discharged.

(5) In any one of the above (1) to (4), the at least one trench may have a planar shape of a U-shape, a ladder shape or a lattice shape. Since the trench is arranged in a wide range of the bonding interface, moisture is easily discharged out through the trench.

(6) In any one of the above (1) to (5), the semiconductor device may be in contact with the silicon layer. The performance of the semiconductor optical device is improved. By discharging the moisture generated at the bonding interface out through the trench, bubbles are less likely to be generated at the bonding interface.

(7) A method of manufacturing a semiconductor optical device includes: bonding a semiconductor device formed of a III-V group compound semiconductor to a silicon layer of a substrate by hydrophilic bonding; and wet-etching the semiconductor device. The silicon layer is provided with a trench, the trench extends from a region overlapping the semiconductor device to a region outside the semiconductor device and is provided with a communicating port that communicates between a portion of the trench in the region overlapping the semiconductor device and a portion of the trench in the region outside the semiconductor device, and the communicating port in the trench is a single communicating port. Since the number of the communicating ports is one, the etchant is less likely to enter into the trench. It is possible to prevent etching of the semiconductor device from the bonding interface. Moisture generated by the hydrophilic bonding can be discharged out through the trench.

(8) In the above (7), the method may include forming a mask before the wet-etching, the mask may be embedded in the portion of the trench in the region outside the semiconductor device, the communicating port may be closed by the mask, and in the wet-etching, a portion of the semiconductor device exposed from the mask may be wet-etched. Holes or the like may be generated in the mask. Since the number of communicating ports included in one trench is one, an etchant is less likely to enter from the communicating port. Etching of the semiconductor device from the bonding interface side can be prevented.

(9) In the above (7) or (8), after the bonding, the trench may be present within a distance of 50 μm from any position at a bonding interface between the substrate and the semiconductor device. Since the distance to the trench is short, moisture reaches the trench and is easily discharged.

(10) In any one of the above (7) to (9), the bonding may be performed at a temperature higher than a room temperature and a vapor pressure lower than an atmosphere pressure. By increasing the temperature, moisture is generated. By reducing the vapor pressure, moisture is easily sucked and discharged to the outside of the bonding interface.

### Details of Embodiments of Present Disclosure

Specific examples of a semiconductor optical device and a method of manufacturing a semiconductor optical device according to embodiments of the present disclosure will be described below with reference to the drawings. It is noted that, the present disclosure is not limited to these examples, but is defined by the scope of the claims, and is intended to include all modifications within the meaning and scope equivalent to the scope of the claims.

### First Embodiment

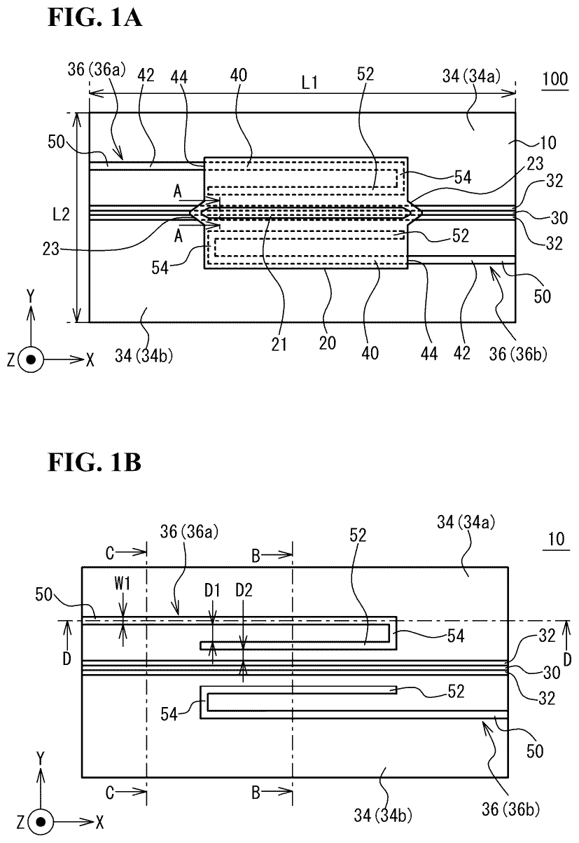

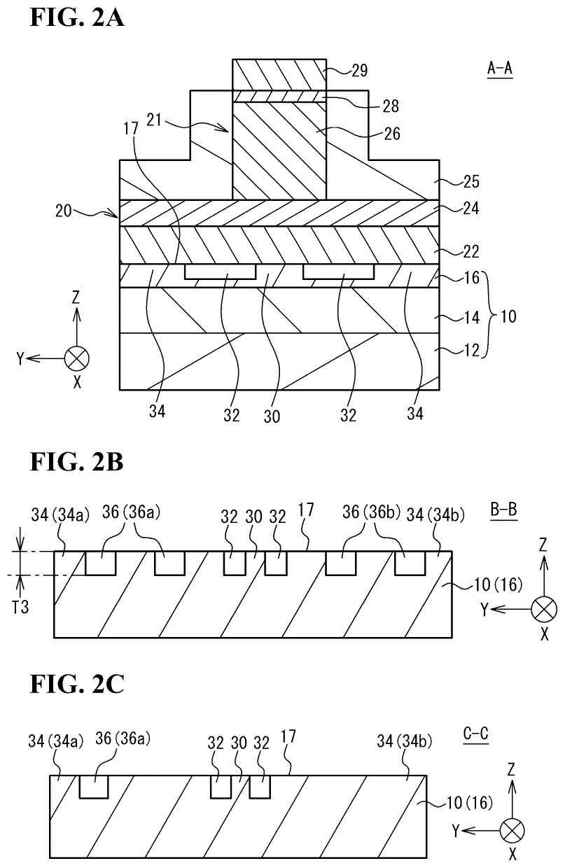

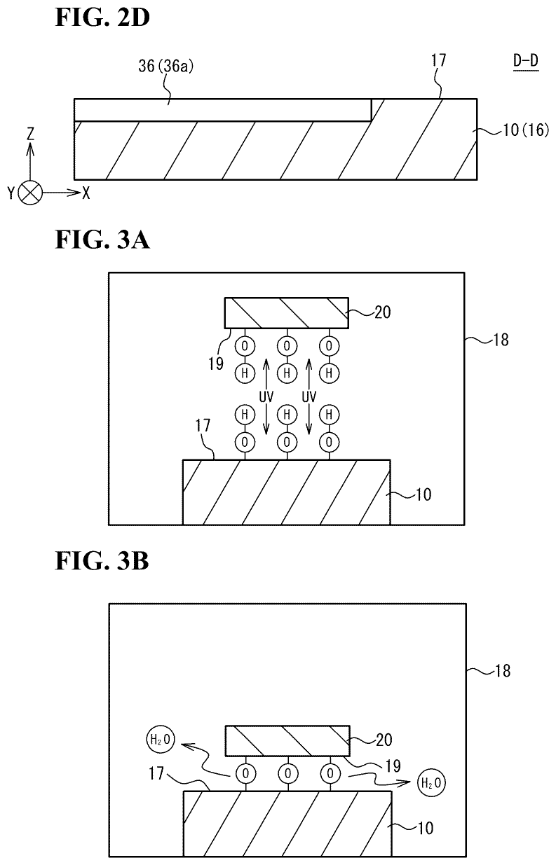

FIG. 1A is a plan view illustrating a semiconductor optical device 100 according to a first embodiment. FIG. 1B is a plan view illustrating a substrate 10. FIG. 2A is a cross-sectional view illustrating semiconductor optical device 100, and illustrates a cross-section taken along line A-A of FIG. 1A. FIGS. 2B to 2D are cross-sectional views of substrate 10, each illustrating a silicon layer 16 of substrate 10, and omitting other layers of substrate 10. FIG. 2B illustrates a cross-section taken along line B-B of FIG. 1B. FIG. 2C illustrates a cross-section taken along line C-C of FIG. 1B. FIG. 2D illustrates a cross-section taken along line D-D of FIG. 1B.

As illustrated in FIG. 1A, semiconductor optical device 100 is a hybrid type device and includes substrate 10 and a semiconductor device 20. Semiconductor device 20 is formed of, for example, a III-V group compound semiconductor and has an optical gain. Semiconductor optical device 100 functions as a semiconductor laser element, an optical modulator, or the like.

Two sides of substrate 10 are parallel to the X-axis. The other two sides of substrate 10 are parallel to the Y-axis. An upper surface of substrate 10 is parallel to the XY plane. The normal line of the upper surface of substrate 10 is parallel to the Z-axis. The X-axis, the Y-axis, and the Z-axis are orthogonal to each other. A length L1 of substrate 10 in the X-axis direction illustrated in FIG. 1A is, for example, 1500 μm. A length L2 in the Y-axis direction is, for example, 500 μm.

As illustrated in FIGS. 1A and 1B, substrate 10 has a waveguide 30, a recess 32, a terrace 34, and is provided with two trenches 36. Recesses 32 are provided on both sides of waveguide 30 in the Y-axis direction. Waveguide 30 and recess 32 are parallel to the X-axis direction. A width of waveguide 30 is, for example, 0.5 μm. A width of recess 32 is, for example, 2 μm. Terrace 34 is provided at a position opposite to waveguide 30 with respect to recess 32.

In the examples of FIGS. 1A and 1B, waveguide 30 is located at the center of substrate 10 in the Y-axis direction. A terrace 34a (first portion) is disposed on one side of waveguide 30, and a terrace 34b (second portion) is disposed on the other side of waveguide 30. One of the two trenches 36 is referred to as a trench 36a, and the other is referred to as a trench 36b. Trench 36a is provided in terrace 34a. Trench 36b is provided in terrace 34b. Trench 36 is a drainage trench for discharging moisture.

As illustrated in FIGS. 1A and 1B, trench 36 has a planar shape of a U-shape. Trench 36 includes a trench 50, a trench 52, and a trench 54. Trench 50 and trench 52 are parallel to the X-axis direction. Trench 54 is parallel to the Y-axis direction. Trench 52 is located closer to waveguide 30 than trench 50 is. Trench 54 is connected to one end of trench 50 and one end of trench 52. Trench 50, trench 52, and trench 54 form a U-shape.

A width W1 of trench 36 illustrated in FIG. 1B is, for example, 3 μm. A distance D1 between trench 50 and trench 52 in the Y-axis direction is, for example, 50 μm or less. A distance D2 between trench 52 and recess 32 is, for example, 50 μm or less.

As illustrated in FIG. 1A, semiconductor device 20 has a mesa 21 and a tapered portion 23. Mesa 21 is parallel to the X-axis and is located above waveguide 30 of substrate 10. Each end of mesa 21 along the X-axis has a tapered shape. Semiconductor device 20 has one tapered portion 23 at each of both ends. One tapered portion 23 is located above waveguide 30 and is tapered along the X-axis direction. The other tapered portion 23 is located above waveguide 30 and is tapered in a direction opposite to the X-axis direction.

As illustrated in FIG. 1A, a portion of trench 36 overlapping semiconductor device 20 is referred to as a portion 40. A portion of trench 36 located outside semiconductor device 20 is referred to as a portion 42. Trench 50 of trench 36 extends from under semiconductor device 20 to outside semiconductor device 20. One end of trench 50 is located outside semiconductor device 20, for example, at an end of substrate 10. A part of trench 50, the entirety of trench 52, and the entirety of trench 54 are located under semiconductor device 20. That is, portion 40 of trench 36 includes trench 52, trench 54, and a part of trench 50, and has a U-shape. Portion 42 of trench 36 includes the other part of trench 50.

Trench 36 has a communicating port 44. Portion 40 of trench 36 overlapping semiconductor device 20 and portion 42 outside semiconductor device 20 communicate with each other at communicating port 44. Communicating port 44 overlaps with an end of semiconductor device 20. The position of communicating port 44 is determined in accordance with the shape and size of semiconductor device 20. The number of communicating ports 44 included in one trench 36 is one.

As illustrated in FIG. 2A, substrate 10 is, for example, a silicon on insulator (SOI) substrate, and includes a substrate 12, a BOX layer 14, and silicon layer 16. Substrate 12 is formed of, for example, silicon (Si). BOX layer 14 is formed of, for example, silicon oxide (SiO₂). The refractive index of silicon layer 16 is 3.45. The refractive index of BOX layer 14 is 1.45, which is lower than that of silicon layer 16. A thickness of BOX layer 14 is, for example, 3 μm. A thickness of silicon layer 16 is, for example, 220 nm. The total thickness of substrate 10 is, for example, 750 μm.

In the Z-axis direction, BOX layer 14 and silicon layer 16 are stacked in this order on one surface of substrate 12. In the Z-axis direction in which a surface of silicon layer 16 opposite to BOX layer 14 is defined as a surface 17, waveguide 30 and terrace 34 are located at the same height and form surface 17 of silicon layer 16. Semiconductor device 20 is bonded to surface 17.

As illustrated in FIGS. 2B and 2C, recess 32 and trench 36 are recessed in the Z-axis direction as compared to surface 17. A depth T3 of trench 36 is, for example, 200 nm. Recess 32 and trench 36 extends from the surface of silicon layer 16, and do not have to reach a surface of BOX layer 14, or may extend to the surface of BOX layer 14, along the Z-axis.

As illustrated in FIG. 2A, semiconductor device 20 includes a cladding layer 22, an active layer 24, a cladding layer 26, and a contact layer 28. Cladding layer 22 is directly in contact with surface 17 of silicon layer 16. Active layer 24, cladding layer 26, and contact layer 28 are stacked in order on a surface of cladding layer 22 opposite to silicon layer 16. Mesa 21 includes cladding layer 26 and contact layer 28, and protrudes in the Z-axis direction. Cladding layer 22 and active layer 24 are provided in a range wider than mesa 21 in the XY plane. Tapered portion 23 includes cladding layer 22 and active layer 24.

An insulating film 25 covers side surfaces of mesa 21 and an upper surface of active layer 24. Insulating film 25 has an opening portion on mesa 21. An electrode 29 is provided in the opening portion. Electrode 29 is electrically connected to contact layer 28. Insulating film 25 has an opening portion (not illustrated) at a position spaced apart from mesa 21. An electrode (not illustrated) electrically connected to cladding layer 22 is provided in the opening portion. The electrode is formed of metal.

Insulating film 25 covers a portion of substrate 10 located outside semiconductor device 20, and is filled in recess 32 of substrate 10 and in a portion of trench 36 located outside semiconductor device 20. Insulating film 25 is formed of, for example, silicon oxide (SiO₂) having a thickness of 1 μm.

Cladding layer 22 is formed of, for example, n-type indium phosphide (n-InP) having a thickness of 0.4 μm. Active layer 24 has a multiple quantum well (MQW) structure, and includes barrier layers and well layers. The plurality of barrier layers and the plurality of well layers are alternately stacked. The barrier layer and the well layer are formed of, for example, i-type gallium indium arsenide phosphide (GaInAsP). Cladding layer 26 is formed of, for example, p-type indium phosphide (p-InP). Contact layer 28 is formed of, for example, p-type gallium indium arsenide (p-GaInAs). The semiconductor layers of semiconductor device 20 may be formed of a III-V group compound semiconductor other than the above.

A voltage is applied to semiconductor device 20 using the electrodes, and carriers are injected into active layer 24. Active layer 24 has an optical gain and generates light by carrier injection. The wavelength of the light is, for example, 1.55 μm. Semiconductor device 20 and substrate 10 are optically and evanescently coupled. Light generated in semiconductor device 20 is distributed in a concentrated manner near mesa 21 of semiconductor device 20. In tapered portion 23, the light is transferred from semiconductor device 20 to waveguide 30 and propagates through waveguide 30.

In order to prevent the loss of light, mesa 21 and tapered portion 23 are formed in bonded semiconductor device 20 by etching or the like. Since semiconductor device 20 has mesa 21, the mode shape becomes stable. In tapered portion 23 of semiconductor device 20, light gradually transitions between semiconductor device 20 and waveguide 30.

In order to improve characteristics described above such as the improvement of the light transition efficiency through tapered portion 23 and the improvement of the light output, semiconductor device 20 and surface 17 of silicon layer 16 are brought into contact with each other without providing an adhesive or the like between semiconductor device 20 and silicon layer 16 of substrate 10. As will be described later, semiconductor device 20 is bonded to silicon layer 16 by hydrophilic bonding.

### Method of Manufacturing

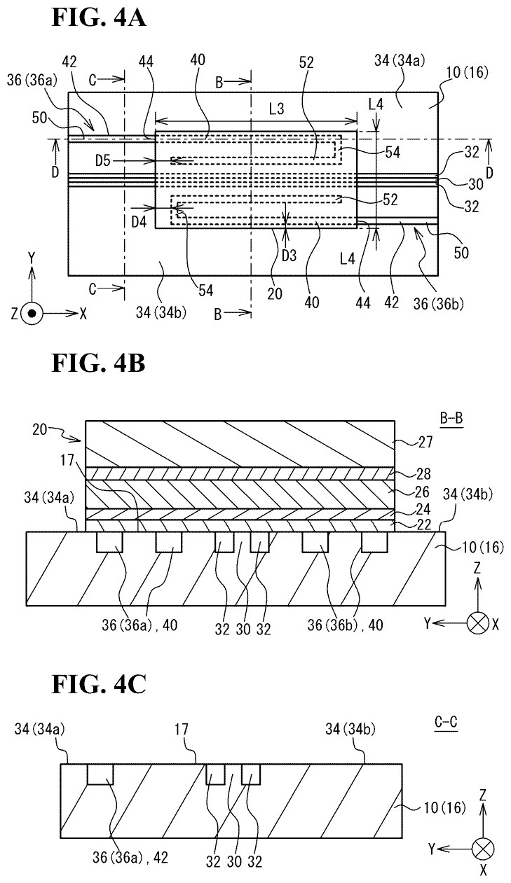

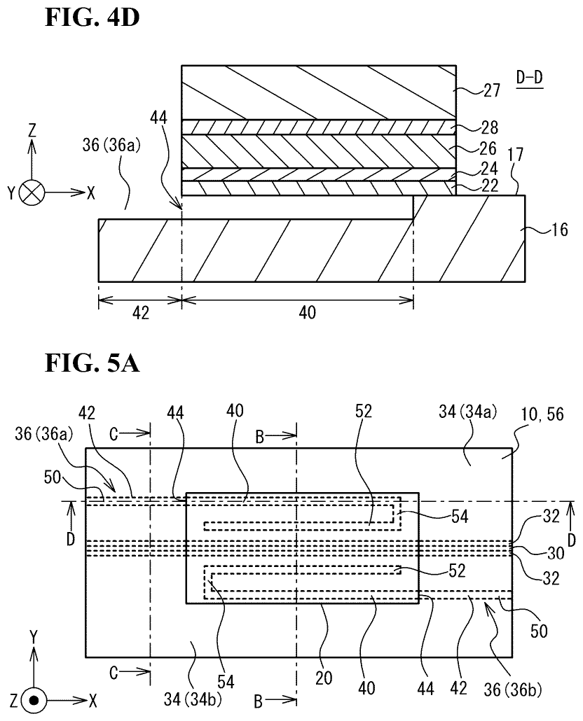

FIGS. 3A and 3B are schematic views each illustrating a method of manufacturing semiconductor optical device 100, and illustrate a bonding step. FIGS. 4A, 5A, 6A, and 7A are plan views each illustrating a method of manufacturing semiconductor optical device 100. FIGS. 4B to 4D, FIGS. 5B to 5D, FIGS. 6B to 6D, and FIGS. 7B to 7D are cross-sectional views each illustrating a method of manufacturing semiconductor optical device 100. In the cross-sectional view of FIG. 4B and the like, silicon layer 16 of substrate 10 is illustrated, and BOX layer 14 or substrate 12 are not illustrated.

Silicon layer 16 of substrate 10 is dry etched to form recess 32 and trench 36 as illustrated in FIG. 1B. Contact layer 28, cladding layer 26, active layer 24, and cladding layer 22 are epitaxially grown on an indium phosphide (InP) substrate, which is a substrate different from substrate 10, by, for example, metal organic chemical vapor deposition (MOCVD) method. The InP substrate is diced to manufacture semiconductor device 20. Semiconductor device 20 immediately after dicing has, for example, a rectangular parallelepiped shape, and does not have a mesa or a tapered portion.

As illustrated in FIGS. 3A and 3B, semiconductor device 20 is bonded to substrate 10. As illustrated in FIG. 3A, the bonding step is performed in a chamber 18. In the atmosphere, one surface 19 of semiconductor device 20 and surface 17 of silicon layer 16 of substrate 10 are irradiated with ultraviolet (UV) rays. Ozone is generated from oxygen in the atmosphere by the ultraviolet rays. Surface 19 and surface 17 are washed with water. Surface 19 of semiconductor device 20 and surface 17 of substrate 10 are hydrophilized. The hydrophilization generates hydroxyl groups (OH) on surface 19 and surface 17.

Surface 19 of semiconductor device 20 is brought into contact with surface 17 of substrate 10, and a load is applied. After being contacted, heating and evacuation are performed. The temperature in chamber 18 is set to, for example, 150 degrees. The vapor pressure in chamber 18 is set to, for example, 1×10⁻² Pa by evacuation. As illustrated in FIG. 3B, heating causes water molecules (H₂O) to be released from the hydroxyl groups, leaving oxygen atoms (O). The oxygen atoms connects surface 19 and surface 17.

As illustrated in FIG. 4A, semiconductor device 20 is bonded to substrate 10. A length L3 of semiconductor device 20 in the X-axis direction is, for example, 800 μm. A length L4 in the Y-axis direction is, for example, 300 μm.

FIG. 4B illustrates a cross-section taken along line B-B of FIG. 4A. FIG. 4C illustrates a cross-section taken along line C-C of FIG. 4A. FIG. 4D illustrates a cross-section taken along line D-D of FIG. 4A. At the time after the bonding and before the etching, semiconductor device 20 has a substrate 27. Substrate 27 is formed of, for example, InP. As illustrated in FIGS. 4A, 4B and 4D, portion 40 of trench 36 is located under semiconductor device 20. As illustrated in FIGS. 4A, 4C, and 4D, portion 42 of trench 36 is located outside semiconductor device 20. As illustrated in FIGS. 4A and 4D, communicating port 44 is formed at the boundary between portion 40 and portion 42.

A distance D3 from trench 52 of trench 36 to an end of semiconductor device 20 in the Y-axis direction illustrated in FIG. 4A is, for example, 50 μm or less. A distance D4 from trench 54 of trench 36 to another end of semiconductor device 20 in the X-axis direction is, for example, 50 μm or less. A distance D5 from another end of trench 52 to an end of semiconductor device 20 in the X-axis direction is, for example, 50 μm or less. At the time after bonding and before wet-etching, trench 36 is present within a distance of, for example, 50 μm from any positions in the bonding interface between substrate 10 and semiconductor device 20.

As described above, moisture is generated by performing hydrophilic bonding. If moisture remains at the bonding interface, the moisture may be vaporized to generate bubbles. The moisture moves from the bonding interface to trench 36 and is discharged out through trench 36. By reducing the vapor pressure in chamber 18 to be lower than the atmosphere pressure, moisture moves through the bonding interface between silicon layer 16 and cladding later 22, reaches trench 36, and is discharged to the outside of semiconductor device 20 in plan view, through communicating port 44 and portion 42.

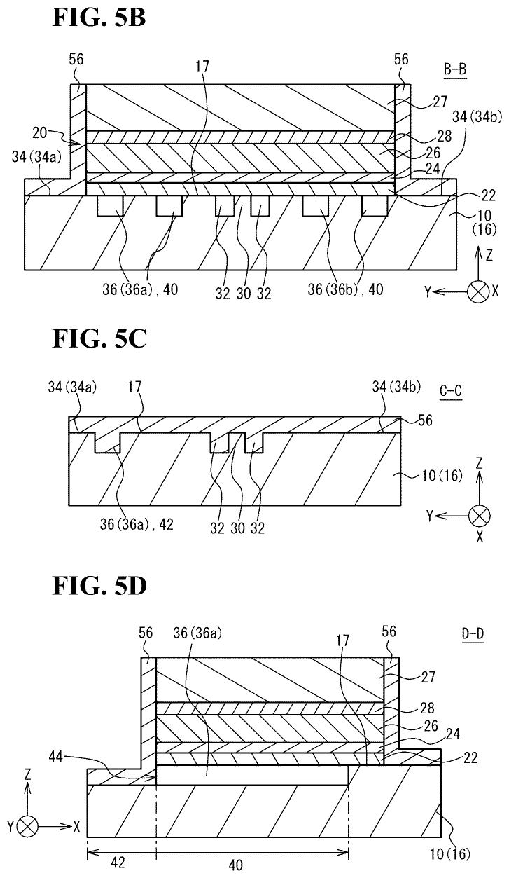

FIG. 5B illustrates a cross-section taken along line B-B of FIG. 5A. FIG. 5C illustrates a cross-section taken along line C-C of FIG. 5A. FIG. 5D illustrates a cross-section taken along line D-D of FIG. 5A. As illustrated in FIGS. 5A to 5D, an insulating film 56 is formed by, for example, a plasma enhanced chemical vapor deposition (PECVD) method. Insulating film 56 is formed of an insulating material such as silicon oxide (SiO2), and covers semiconductor device 20 and surface 17 of substrate 10.

Insulating film 56 is covered with a resist mask (not illustrated), and resist patterning is performed. An opening portion is formed at a position of the resist mask overlapping semiconductor device 20 in the Z-axis direction. A portion of insulating film 56 exposed from the resist mask is removed by hydrofluoric acid. After the etching with hydrofluoric acid, the resist mask is removed. As illustrated in FIGS. 5B and 5D, substrate 27 of semiconductor device 20 is exposed from insulating film 56.

As illustrated in FIGS. 5B and 5D, insulating film 56 is not embedded in portion 40 of trench 36 overlapping semiconductor device 20. As illustrated in FIGS. 5C and 5D, insulating film 56 is embedded in portion 42 of trench 36 located outside semiconductor device 20. As illustrated in FIG. 5D, communicating port 44 is closed with insulating film 56. As illustrated in FIG. 5B, insulating film 56 is not embedded in the portion of recess 32 overlapping semiconductor device 20. As illustrated in FIG. 5C, insulating film 56 is embedded in a portion of recess 32 located outside semiconductor device 20.

Wet-etching is performed using insulating film 56 as a mask. Substrate 27 of semiconductor device 20 is removed by wet-etching. A hydrochloric acid (HCl)-based solution is used as an etchant.

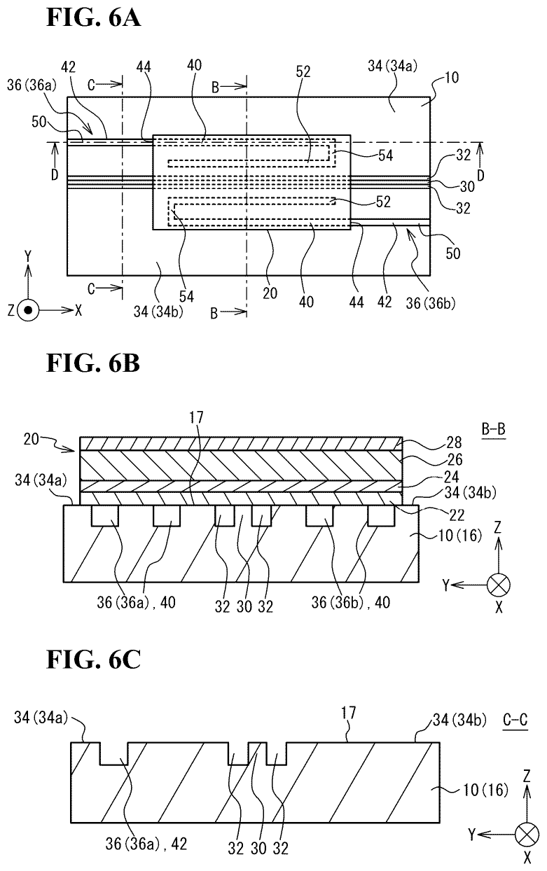

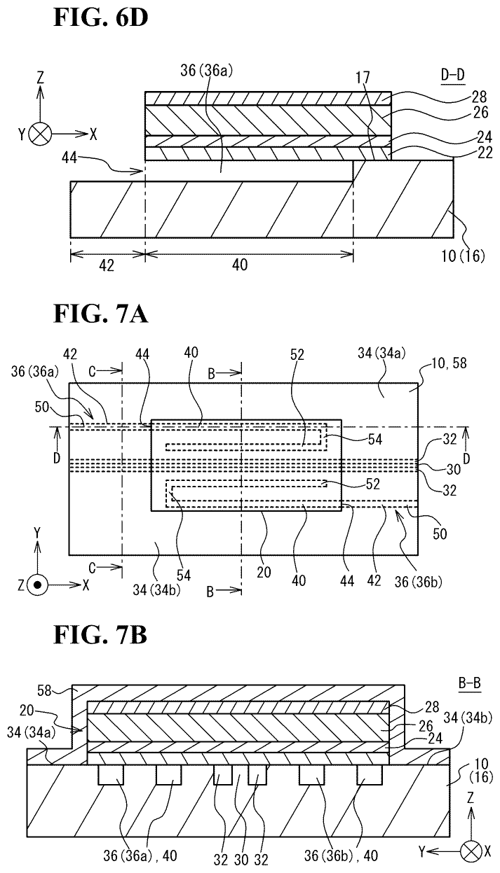

FIG. 6B illustrates a cross-section taken along line B-B of FIG. 6A. FIG. 6C illustrates a cross-section taken along line C-C of FIG. 6A. FIG. 6D illustrates a cross-section taken along line D-D of FIG. 6A. As illustrated in FIGS. 6A to 6D, substrate 27 is removed by wet-etching. The layers from contact layer 28 to cladding layer 22 remain. After the wet-etching, contact layer 28 is exposed. After the wet-etching, insulating film 56 used as a mask is removed. Surface 17 of substrate 10 is exposed.

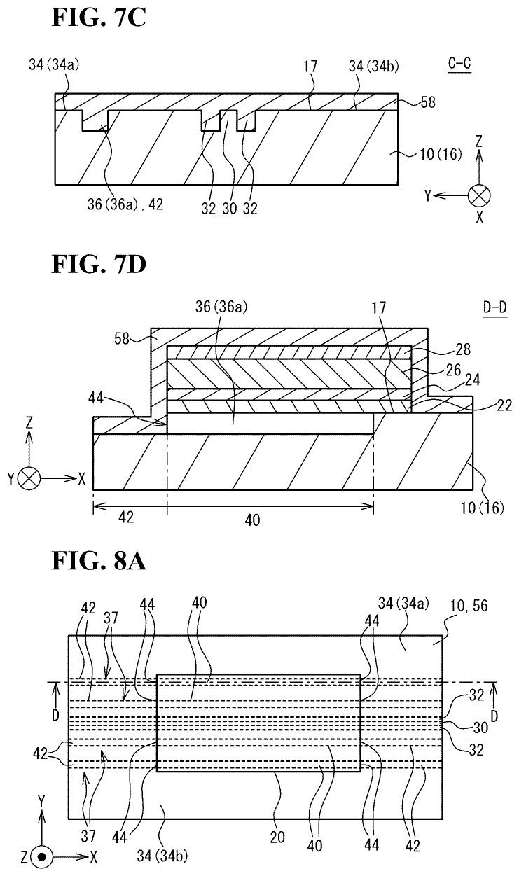

FIG. 7B illustrates a cross-section taken along line B-B of FIG. 7A. FIG. 7C illustrates a cross-section taken along line C-C of FIG. 7A. FIG. 7D illustrates a cross-section taken along line D-D of FIG. 7A. As illustrated in FIGS. 7A to 7D, an insulating film 58 is provided by a PECVD method or the like. In the steps illustrated in FIG. 7A and thereafter, the resist pattern is transferred to form a pattern on insulating film 58. Dry-etching, wet-etching, or the like are performed using insulating film 58 as a mask. Another mask is further provided, and wet-etching or the like is performed on a portion of semiconductor device 20 exposed from the mask. Semiconductor device 20 is etched to form mesa 21 and tapered portion 23 illustrated in FIG. 1A. Electrodes are formed by vacuum deposition or the like.

As described above, the wet-etching is performed a plurality of times in the manufacturing process. In these wet-etchings, a hydrochloric acid-based etchant or the like is used. Since the number of communicating ports 44 included in one trench 36 is one, the etchant is less likely to enter portion 40 of trench 36. Etching of semiconductor device 20 from the bonding interface is prevented.

### First Comparative Example

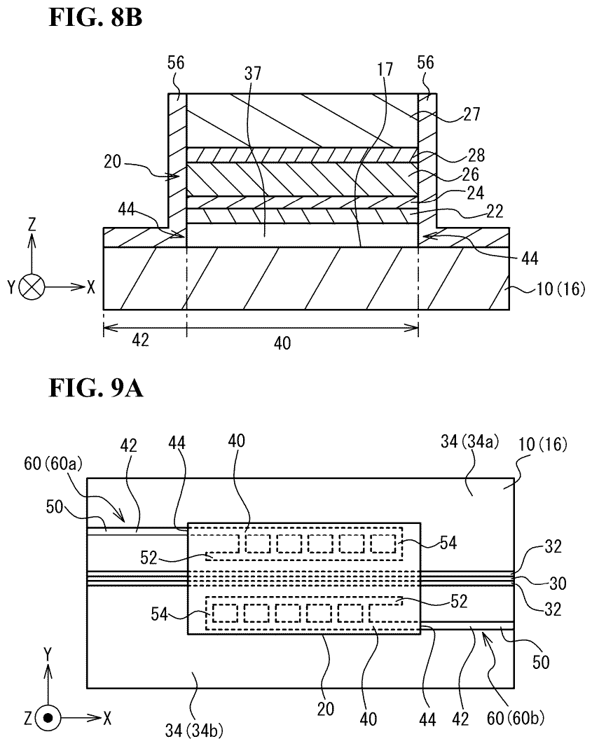

FIG. 8A is a plan view illustrating a method of manufacturing a semiconductor optical device according to a first comparative example. FIG. 8B is a cross-sectional view illustrating a cross-section taken along line D-D of FIG. 8A. FIGS. 8A and 8B illustrate steps corresponding to FIGS. 5A to 5D.

As illustrated in FIG. 8A, substrate 10 is provided with four trenches 37. Two trenches 37 are provided in terrace 34a. Two trenches 37 are provided in terrace 34b. Trench 37 is linear, parallel to the X-axis direction, and extends from one end to the other end of substrate 10 in the X-axis direction. One trench 37 has one portion 40, two portions 42, and two communicating ports 44.

As illustrated in FIG. 8B, two communicating ports 44 are covered by insulating film 56. However, a minute hole may be generated in insulating film 56, and the coverage by insulating film 56 may become insufficient. In such a case, communicating port 44 is not closed with insulating film 56, and can be an entrance for immersion of the etchant. One trench 37 has two communicating ports 44. Substrate 10 has eight communicating ports 44. Since the number of communicating ports 44 is large, the etchant easily enters portion 40 of trench 37 from communicating ports 44. When the etchant enters into portion 40 of trench 37, semiconductor device 20 is etched from the bottom of cladding layer 22. Such unintended etching may cause peeling of semiconductor device 20, performance failure, and the like.

According to the first embodiment, as illustrated in FIG. 4A and the like, the number of communicating ports 44 included in one trench 36 is one. The number of communicating ports 44 included in substrate 10 is two, which is smaller than eight in the first comparative example. Since the number of communicating ports 44 is small, the etchant is less likely to enter portion 40 of trench 36. Etching of semiconductor device 20 from the bonding interface can be prevented. Semiconductor device 20 is less likely to be peeled off or to have a performance failure, and the number of defective products is reduced.

As illustrated in FIGS. 5A to 5D and FIGS. 7A to 7D, the mask formation and the wet-etching are repeated a plurality of times. The portion covered by the mask is not in contact with the etchant and is not etched. However, holes or the like may be generated in the mask. According to the first embodiment, since the number of communicating ports 44 in one trench 36 is one, the etchant is less likely to enter into portion 40 of trench 36. Etching of semiconductor device 20 from the bonding interface can be prevented.

As illustrated in FIGS. 1A and 4A, substrate 10 is provided with two trenches 36. Moisture can be discharged from the bonding interface through two trenches 36. Each of two trenches 36 has one communicating port 44. The etchant is less likely to enter two trenches 36. It is possible to prevent semiconductor device 20 formed of a III-V group compound semiconductor from being etched from the bonding interface.

Terrace 34a is located on one side of waveguide 30. On the opposite side, terrace 34b is located. Trench 36a is provided in terrace 34a. Trench 36b is provided in terrace 34b. The number of communicating ports 44 included in each of trench 36a and trench 36b is one. In both of terraces 34a and 34b, moisture can be discharged and etchant can be prevented from entering into both of terraces 34a and 34b.

As illustrated in FIGS. 1A and 1B, portion 40 of trench 36 has a planar shape of a U-shape. Trench 52 is located near waveguide 30. Trench 50 is located near an end of semiconductor device 20. Since trench 36 is arranged in a wide range of the bonding interface, moisture is easily discharged out through trench 36. As will be described later, the number of trenches 36 may be two or more. Trench 36 may have a planar shape other than a U-shape.

The shorter the distance from the position where the moisture is generated to trench 36, the more easily the moisture reaches trench 36 and is discharged. The distances D3, D4, and D5 between trench 36 and the ends of semiconductor device 20 are all, for example, 50 μm or less. The distance D1 between trench 50 and trench 52 of trench 36 is, for example, 50 μm or less. The distance D2 between recess 32 and trench 36 is, for example, 50 μm. In the XY plane, trench 36 is present within a distance of, for example, 50 μm from any position at the bonding interface. Moisture reaches trench 36 and is easily discharged. Thus, moisture generated at any positions is less likely to remain in the bonding interface.

The distances D1, D2, D3, D4, and D5 may be, for example, 40 μm or less, 50 μm or less, 60 μm or less, or 100 μm or less. That is, trench 36 may be present within a distance of, for example, 40 μm, 50 μm, 60 μm, or 100 μm from any position at the bonding interface.

As illustrated in FIG. 2A, semiconductor device 20 is in contact with surface 17 of substrate 10. The performance of semiconductor optical device 100 is improved. In order to directly bond semiconductor device 20 to substrate 10, hydrophilic bonding is performed. By discharging moisture generated by hydrophilic bonding out through trench 36, bubbles are less likely to be generated at the bonding interface.

The step of hydrophilic bonding is performed at a temperature higher than a room temperature and at a vapor pressure lower than an atmosphere pressure. When the temperature is, for example, 100 degrees or higher or 150 degrees or higher, moisture is generated from the bonding interface. By reducing the vapor pressure, moisture is easily sucked and discharged to the outside of the bonding interface. The vapor pressure in chamber 18 is set to, for example, 1×10⁻² Pa or less, 5×10⁻² Pa or less, or 10×10⁻² Pa or less.

### Second Embodiment

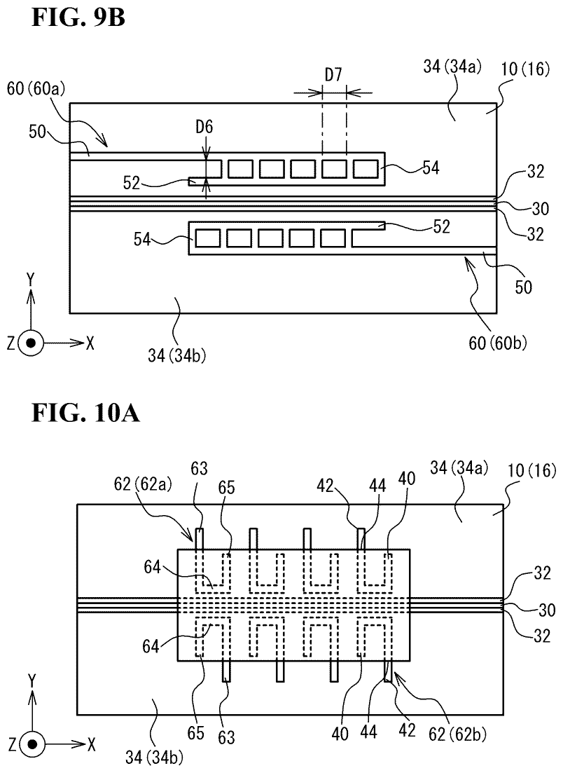

FIG. 9A is a plan view illustrating a method of manufacturing a semiconductor optical device according to a second embodiment, and illustrates a step corresponding to FIG. 4A. FIG. 9B is a plan view illustrating substrate 10. The description of the same configuration as that of the first embodiment will be omitted.

As illustrated in FIGS. 9A and 9B, silicon layer 16 of substrate 10 is provided with two trenches 60. A trench 60a of two trenches 60 is provided in terrace 34a. A trench 60b of two trenches 60 is provided in terrace 34b.

Trench 60 includes trench 50, trench 52, and a plurality of trenches 54. One end of each trench 54 is connected to trench 50. The other end of each trench 54 is connected to trench 52. Each trench 54 extends in the Y-axis direction. The plurality of trenches 54 are arranged along the X-axis direction. The shape formed by trench 50, trench 52, and the plurality of trenches 54 is a ladder shape. The number of trenches 54 in one trench 60 may be six or more, or may be six or less. A distance D6 between trenches 50 and 52 in the Y-axis direction illustrated in FIG. 9B is, for example, 50 μm or less. A distance D7 between two adjacent trenches 54 in the X-axis direction is, for example, 50 μm or less.

As illustrated in FIG. 9A, trench 50 of trench 60 extends from under semiconductor device 20 to outside semiconductor device 20. A part of trench 50, the entirety of trench 52, and the entirety of plurality of trenches 54 are located under semiconductor device 20. That is, portion 40 of trench 60 includes the entirety of trench 52, the plurality of trenches 54, and a part of trench 50, and has a ladder shape. Portion 42 includes the other part of trench 50. The number of communicating ports 44 included in one trench 60 is one.

According to the second embodiment, the number of communicating ports 44 included in one trench 60 is one. The number of communicating ports 44 included in substrate 10 is two. Since the number of communicating ports 44 is small, the etchant is less likely to enter portion 40 of trench 60. Etching of semiconductor device 20 from the bonding interface can be prevented.

As illustrated in FIG. 9A, portion 42 of trench 60 has a planar shape of a ladder shape. Trench 50 of trench 60 is located near an end of semiconductor device 20. Trench 52 is located near waveguide 30. The plurality of trenches 54 are connected to trench 50 and trench 52. Since trench 60 is arranged in a wide range of the bonding interface, moisture is easily discharged out through trench 60.

### Third Embodiment

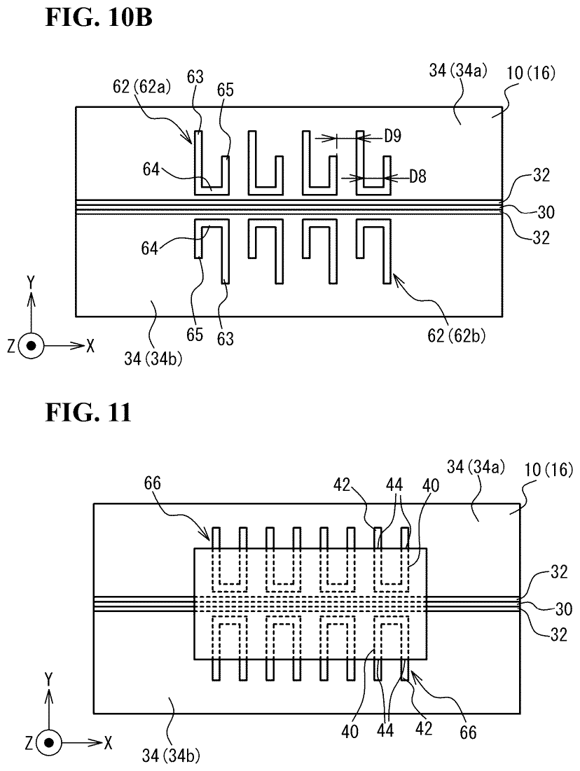

FIG. 10A is a plan view illustrating a method of manufacturing a semiconductor optical device according to a third embodiment, and illustrates a step corresponding to FIG. 4A. FIG. 10B is a plan view illustrating substrate 10. The description of the same configuration as that of the first embodiment or the second embodiment will be omitted.

As illustrated in FIGS. 10A and 10B, silicon layer 16 of substrate 10 is provided with eight trenches 62. Four trenches 62a of eight trenches 62 are provided in terrace 34a. Four trenches 62a are arranged in the X-axis direction. Four trenches 62b of eight trenches 62 are provided in terrace 34b. Four trenches 62b are arranged in the X-axis direction.

Trench 62 includes a trench 63, a trench 64, and a trench 65. Trench 63 and trench 65 are parallel to the Y-axis direction. Trench 64 is parallel to the X-axis direction and is located between trench 63 and trench 65. Trench 64 is connected to one end of trench 63 and one end of trench 65. A distance D8 between trench 63 and trench 65 illustrated in FIG. 10B is, for example, 50 μm or less. A distance D9 between two adjacent trenches 62 is, for example, 50 μm or less.

As illustrated in FIG. 10A, trench 63 of trench 62 extends from under semiconductor device 20 to outside semiconductor device 20. The entirety of trench 64 and the entirety of trench 65 are located under semiconductor device 20. That is, portion 40 of trench 62 includes trench 64, trench 65, and a part of trench 63, and has a U-shape. Portion 42 includes the other part of trench 63. The number of communicating ports 44 included in one trench 62 is one.

### Second Comparative Example

FIG. 11 is a plan view illustrating a method of manufacturing a semiconductor optical device according to the second comparative example, and illustrates a step corresponding to FIG. 4A. Silicon layer 16 of substrate 10 has eight trenches 66. Four trenches 66 are provided in terrace 34a and arranged in the X-axis direction. Four trenches 66 are provided in terrace 34b and arranged in the X-axis direction. One trench 66 has two communicating ports 44. Substrate 10 has 16 communicating ports.

Moisture generated by the hydrophilic bonding is discharged out through trench 66. However, since the number of communicating ports 44 is large, the etchant is likely to enter into. Semiconductor device 20 may be etched from the side near the bonding interface.

According to the third embodiment, the number of communicating ports 44 included in one trench 62 is one. The number of communicating ports 44 included in substrate 10 is eight, which is smaller than that of the second comparative example. Since the number of communicating ports 44 is small, the etchant is less likely to enter portion 40 of trench 62. Etching of semiconductor device 20 from the bonding interface side can be prevented.

Substrate 10 has eight trenches 62. Moisture can be discharged from the bonding interface through eight trenches 62. Four trenches 62a are provided in terrace 34a. Four trenches 62b are provided in terrace 34b. In both of terraces 34a and 34b, moisture can be discharged and etchant can be prevented from entering into. The number of trenches 62 may be eight or more or eight or less.

Trench 62 has a planar shape of a U-shape. Since trench 62 is arranged in a wide range of the bonding interface, moisture is easily discharged out through trench 62.

### Fourth Embodiment

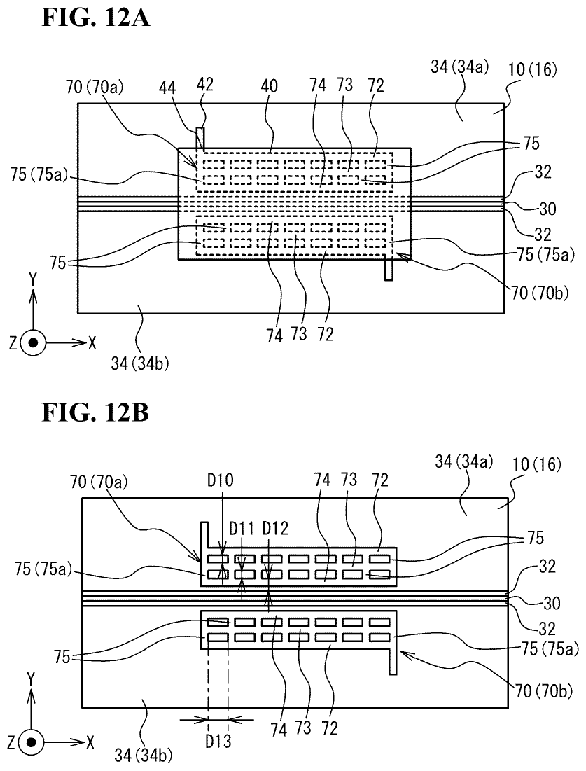

FIG. 12A is a plan view illustrating a method of manufacturing a semiconductor optical device according to a fourth embodiment, and illustrates a step corresponding to FIG. 4A. FIG. 12B is a plan view illustrating substrate 10. The description of the same configuration as that of any one of the first embodiment to the third embodiment will be omitted.

As illustrated in FIGS. 12A and 12B, silicon layer 16 of substrate 10 is provided with two trenches 70. A trench 70a of two trenches 70 is provided in terrace 34a. A trench 70b of two trenches 70 is provided in terrace 34b.

Trench 70 includes a trench 72, a trench 73, a trench 74, and a plurality of trenches 75. Trench 72, trench 73, and trench 74 are parallel to the X-axis direction. Trench 75 is parallel to the Y-axis direction. Trench 72 is located closer to the end of semiconductor device 20 than trench 73 and trench 74 are. Trench 74 is located closer to waveguide 30 than trench 72 and trench 73 are. Trench 73 is located between trench 72 and trench 74. Trench 75 is connected to trench 72, trench 73, and trench 74.

A distance D10 between trench 72 and trench 73 in the Y-axis direction illustrated in FIG. 12B is, for example, 50 μm or less. A distance D11 between trench 73 and trench 74 is, for example, 50 μm or less. A distance D12 between trench 74 and recess 32 is, for example, 50 μm or less. A distance D13 between adjacent trenches 75 in the X-axis direction is, for example, 50 μm or less.

A trench 75a, which is one of the plurality of trenches 75, extends from a region overlapping semiconductor device 20 to the region outside of semiconductor device 20. The entirety of the plurality of trenches 75 except for trench 75a is located under semiconductor device 20. The entirety of trenches 72, 73, and 74 is located under semiconductor device 20. Portion 40 of trench 70 includes the plurality of trenches 75, trench 72, trench 73, trench 74, and a part of trench 75a, and has a lattice shape. Portion 42 includes the other part of trench 75a. The number of communicating ports 44 included in one trench 70 is one.

According to the fourth embodiment, the number of communicating ports 44 included in one trench 70 is one. The number of communicating ports 44 included in substrate 10 is two, which is smaller than that of the second comparative example. The etchant is less likely to enter portion 40 of trench 70. Etching of semiconductor device 20 from the bonding interface side can be prevented.

Substrate 10 has two trenches 70. Trench 70a is provided in terrace 34a. Trench 70b is provided in terrace 34b. Trench 70 has a planar shape of a lattice shape. Since trench 70 is arranged in a wide range of the bonding interface, moisture is easily discharged out through trench 70. The trench may have a planar shape any of a U-shape, a ladder shape, and a lattice shape, or may be other shapes.

### Fifth Embodiment

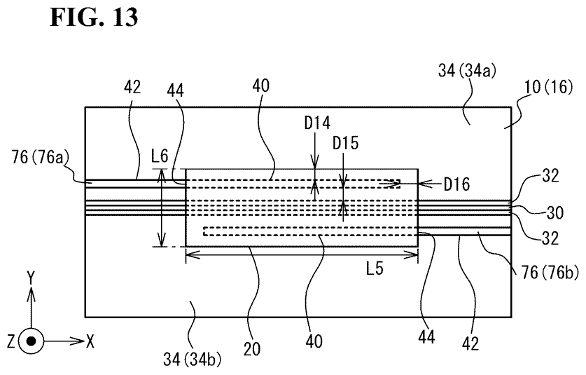

FIG. 13 is a plan view illustrating a method of manufacturing a semiconductor optical device according to a fifth embodiment, and illustrates a step corresponding to FIG. 4A. The description of the same configuration as that of any one of the first embodiment to the fourth embodiment will be omitted. A length L5 of semiconductor device 20 in the X-axis direction is, for example, 800 μm. A length L6 in the Y-axis direction is smaller than the length L4 in FIG. 4A, for example, 200 μm or less.

As illustrated in FIG. 13, silicon layer 16 of substrate 10 is provided with two trenches 76. A trench 76a of two trenches 76 is provided in terrace 34a. A trench 76b of two trenches 76 is provided in terrace 34b.

Trench 76 is linear and parallel to the X-axis direction. Trench 76 extends from a position overlapping semiconductor device 20 to the outside of semiconductor device 20. One end of trench 76 is located under semiconductor device 20. The other end is located outside semiconductor device 20. The number of communicating ports 44 included in one trench 76 is one.

A distance D14 between trench 76 and an end of semiconductor device 20 in the Y-axis direction is, for example, 50 μm or less. A distance D15 between trench 76 and recess 32 is, for example, 50 μm or less. A distance D16 between trench 76 and an end of semiconductor device 20 in the X-axis direction is, for example, 50 μm or less.

According to the fifth embodiment, the number of communicating ports 44 included in one trench 76 is one. The number of communicating ports 44 included in substrate 10 is two. Since the number of communicating ports 44 is small, the etchant is less likely to enter portion 40 of trench 76. Etching of semiconductor device 20 from the bonding interface side can be prevented.

As in the first to fifth embodiments, the number and shape of the trenches can be changed. The drainage performance and bonding strength are also changed by changing the number of trenches and the like. By increasing the number of the trenches, the drainage performance is improved and the area of the bonding interface is reduced. The smaller the area of the bonding interface, the lower the bonding strength. The larger the area of the bonding interface, the higher the bonding strength. When the number of the trenches is reduced, the drainage performance is lowered, the bonding area is increased, and the bonding strength is increased.

For example, the number and shape of the trenches are determined in accordance with the size of semiconductor device 20 at the time of bonding so that the trenches are arranged within a distance of 50 μm from every position at the bonding interface. When the distance of water movement to the trench is within 50 μm, water can be effectively discharged. The larger the semiconductor device 20 in the XY plane, the wider the bonding interface. As in the first to fourth embodiments, the trench has a U-shape, a ladder shape, or a lattice shape. A plurality of trenches may be provided. The distance of water movement to the trench is shortened. When semiconductor device 20 is small, the trench may have a linear shape as in the fifth embodiment. By adopting the trench as described above, both dehydration performance and bonding strength can be achieved.

The first embodiment to the fifth embodiment may be combined. The trench of any one of the first embodiment to the fifth embodiment is provided in a portion included in terrace 34a of the bonding interface. Another trench of the first embodiment to the fifth embodiment is provided in a portion included in terrace 34b of the bonding interface.

Although the embodiments of the present disclosure have been described in detail, the present disclosure is not limited to the specific embodiments, and various modifications and changes can be made within the scope of the gist of the present disclosure described in the claims.

What is claimed is:

1. A semiconductor optical device comprising:
a substrate including a silicon layer; and
a semiconductor device formed of a III-V group compound semiconductor and bonded to the silicon layer of the substrate,
wherein the silicon layer is provided with at least one trench,
the at least one trench extends from a region overlapping the semiconductor device to a region outside the semiconductor device and is provided with a communicating port that communicates between a portion of the at least one trench in the region overlapping the semiconductor device and a portion of the at least one trench in the region outside the semiconductor device, and
the communicating port in the at least one trench is a single communicating port.

2. The semiconductor optical device according to claim 1,
wherein the at least one trench includes a plurality of trenches, and
the communicating port in each of the plurality of trenches is a single communicating port.

3. The semiconductor optical device according to claim 1,
wherein the silicon layer includes a waveguide,
the silicon layer has a first portion located on a side and a second portion located on an opposite side with reference to the waveguide, and
the at least one trench is provided in each of the first portion and the second portion.

4. The semiconductor optical device according to claim 1, wherein the at least one trench is present within a distance of 50 μm from any position at a bonding interface between the substrate and the semiconductor device.

5. The semiconductor optical device according to claim 1, wherein the at least one trench has a planar shape of a U-shape, a ladder shape or a lattice shape.

6. The semiconductor optical device according to claim 1, wherein the semiconductor device is in contact with the silicon layer.

7. A method of manufacturing a semiconductor optical device, the method comprising:
bonding a semiconductor device formed of a III-V group compound semiconductor to a silicon layer of a substrate by hydrophilic bonding; and
wet-etching the semiconductor device,
wherein the silicon layer is provided with a trench,
the trench extends from a region overlapping the semiconductor device to a region outside the semiconductor device and is provided with a communicating port that communicates between a portion of the trench in the region overlapping the semiconductor device and a portion of the trench in the region outside the semiconductor device, and
the communicating port in the trench is a single communicating port.

8. The method of manufacturing a semiconductor optical device according to claim 7,
wherein the method includes forming a mask before the wet-etching,
the mask is embedded in the portion of the trench in the region outside the semiconductor device,
the communicating port is closed by the mask, and
in the wet-etching, a portion of the semiconductor device exposed from the mask is wet-etched.

9. The method of manufacturing a semiconductor optical device according to claim 7, wherein after the bonding, the trench is present within a distance of 50 μm from any position at a bonding interface between the substrate and the semiconductor device.

10. The method of manufacturing a semiconductor optical device according to claim 7, wherein the bonding is performed at a temperature higher than a room temperature and a vapor pressure lower than an atmosphere pressure.
